(19) United States
(12) Patent Application Publication
(10) Pub. No.: US 2023/0402300 A1
(43) Pub. Date: Dec. 14, 2023

(54) REMOVAL METHOD, REMOVAL TOOL AND SEMICONDUCTOR COMPONENT

(71) Applicant: ams-OSRAM International GmbH, Regensburg (DE)

(72) Inventor: Michael ZITZLSPERGER, Regensburg (DE)

(21) Appl. No.: 18/033,651

(22) PCT Filed: Oct. 5, 2021
(86) PCT No.: PCT/EP2021/077384

§ 371 Date: Apr. 25, 2023

(30) Foreign Application Priority Data
Nov. 4, 2020 (DE) 10 2020 129 064.0

(51) Int. Cl. H01L 21/67; B32B 43/00

(52) U.S. Cl. CPC H01L 21/67132; B32B 43/006

(57) ABSTRACT

A method for removing a protective film from a semiconductor component includes providing the semiconductor component having the protective film on a component upper side. The protective film protrudes beyond the component upper side at a longitudinal side. The method also includes separating the protective film from the component upper side with a removal tool which has a removal opening. The separating of the protective film from the component upper side includes guiding the removal tool next to the semiconductor component along the longitudinal side in a direction transverse to the component upper side while it bears on the protective film so that the protective film is bent by the removal tool in a direction toward a side face of the semiconductor component, and retracting the removal tool so that the protective film catches in the removal opening and the protective film is detached from the component upper side.

A method for removing a protective film from a semiconductor component is provided. A removal tool and a semiconductor component for such a method are furthermore provided.

An object to be achieved consists in providing a method with which a protective film can be removed efficiently from a semiconductor component, such as a light-emitting diode.

This object is achieved inter alia by a method having the features of patent claim 1. The other claims relate to preferred developments.

According to at least one embodiment, the semiconductor component is an optoelectronic semiconductor component. For example, the semiconductor component is then a light-emitting diode or an LED lamp.

According to at least one embodiment, the method comprises the step of providing the semiconductor component. In this case, a protective film is located on a component upper side of the semiconductor component. The protective film is, in particular, adapted to protect an optoelectronic semiconductor chip, such as a light-emitting diode chip, of the semiconductor component during transport and mounting. For example, the protective film is a transparent or semitransparent film which is adhesively bonded on the component upper side.

According to at least one embodiment, the method comprises the step of separating the protective film from the component upper side. This separation is carried out with at least one removal tool, which has one or more removal openings. Preferably, precisely one removal tool is used.

According to at least one embodiment, the protective film protrudes beyond the component upper side at a longitudinal side, as seen in extension of the component upper side. That is to say, the protective film overhangs from the component upper side at the longitudinal side.

According to at least one embodiment, the separation of the protective film comprises guiding the removal tool next to the semiconductor component along the longitudinal side in a direction transverse to the component upper side, particularly in a direction perpendicular to the component upper side. In other words, the removal tool is moved transversely, preferably perpendicularly or approximately perpendicularly, to the component upper side. The removal tool in this case preferably approaches a plane that is defined by a component lower side of the semiconductor component. The component lower side in this case lies opposite the component upper side. The removal tool may be guided as far as this plane.

According to at least one embodiment, the removal tool is guided along the protective film while bearing on it, so that the protective film is bent by the removal tool in a direction toward a side face and/or in a direction toward the component lower side of the semiconductor component. The removal tool in this case preferably does not touch the semiconductor component, but only touches the protective film, particularly in the region of a shaft of the removal tool.

According to at least one embodiment, the separation comprises retracting the removal tool. This retraction is preferably carried out in the opposite direction to the previous guiding of the removal tool. That is to say, a reversal of the movement direction of the removal tool may take place. In this way, the protective film catches in the removal opening and the protective film is detached from the component upper side. The catching may be passive catching, i.e. merely due to the geometry of the removal opening and due to properties of the protective film, or the catching is active catching, in particular by a configuration of the removal opening being changed.

It is also possible that the removal tool, insofar as space available on the protective film allows, also executes a horizontal or oblique movement direction at least in part. That is to say, the movement direction is preferably predominantly oriented perpendicularly to the component upper side, although it need not run exclusively perpendicularly to the component upper side.

In at least one embodiment, the method for removing a protective film from a semiconductor component comprises the following steps, particularly in the order indicated:
A) providing the semiconductor component having the protective film on a component upper side, and
B) separating the protective film from the component upper side with a removal tool, which has a removal opening,
the protective film in step A) protruding beyond the component upper side at a longitudinal side, as seen in extension of the component upper side, and
step B) comprising the following substeps, preferably in the order indicated:
B1) guiding the removal tool next to the semiconductor component along the longitudinal side in a direction transverse to the component upper side while it bears on the protective film, so that the protective film is bent by the removal tool in a direction toward a side face of the semiconductor component, and B2) retracting the removal tool so that the protective film catches in the removal opening and the protective film is detached from the component upper side.

The method described here is aimed in particular at SMT components with a protective film. SMT stands for Surface Mount Technology in this context. The protective film may be separated with this method even under narrow space conditions. In particular, it is possible that the method may be carried out automatically or in an automated fashion with the removal tool.

It is often desired for LED-based light sources to be delivered with a protective film over a light-emitting face. Many different parameters are in this case possible, particularly in respect of a configuration of the protective film, such as its shape, how far the protective film protrudes beyond the semiconductor component, or the way in which adhesive faces for fastening the protective film are configured. The requirements of the method with which the protective film is intended to be separated again, for instance after soldering and mounting of further component parts, for example on a circuit board such as a printed circuit board, abbreviated to PCB, may be correspondingly high.

Protective films are often separated manually. For large batch numbers or in narrow space conditions, this is not practicable.

With the method described here, the protective film is separated by a suitable removal tool. The removal tool is, for example, configured like a chisel and has a slot or an indentation as a removal opening close to a lower end. This opening runs obliquely downward, and a lower edge of the removal opening may be sharp-edged or configured with teeth or spikes.

In particular, the removal tool is therefore guided downward next to the semiconductor component in the direction of the circuit board, on which the semiconductor component has preferably been fastened beforehand. A tab or an overhang of the cover film is in this case pressed resiliently downward and slides along a shaft, for example a chisel-shaped shaft, of the removal tool. When the removal tool is lifted back up, the protective film is threaded into the removal opening of the removal tool and jams or catches there, for example on the sharp or spiked edge, and is thereby lifted up and separated from the semiconductor component.

In addition, the clamping effect of the removal tool on the protective film may also be bought about actively by the shaft of the removal tool being configured in multiple parts, especially in two parts, and the slot or the indentation, which may form the removal opening, being narrowed after the protective film has been threaded.

According to at least one embodiment, the protective film in step A) is fastened on the semiconductor component by means of an adhesive. Preferably, the adhesive is applied only locally between the protective film and the semiconductor component, although alternatively it may also be present surface-wide.

According to at least one embodiment, the adhesive is applied only along two mutually opposite transverse sides of the component upper side. The transverse sides are in this case oriented transversely, preferably perpendicularly, to the longitudinal side as seen in a plan view of the component upper side. The transverse sides may each be longer than the longitudinal side.

According to at least one embodiment, the removal opening is formed by a slot or by a notch. The removal opening extends partially or fully along the longitudinal side. That is to say, the removal opening may be elongated and be as wide as or wider than the protective film along the longitudinal side. Alternatively, the removal opening may be relatively narrow and extend only along a part of the longitudinal side, for example along at most 60% or 40% of the longitudinal side. It is possible for the removal opening to be in the shape of a trapezoid or parallelogram as seen in cross section. If the removal opening extends fully along the longitudinal side, the removal tool preferably comprises a frame which lies next to the protective film as seen along the longitudinal side.

According to at least one embodiment, the removal opening extends at an angle of at least 0° or at least 30° or at least 40° and/or at most 70° or at most 60° or at most 50° away from the component upper side and toward the component lower side. That is to say, the removal opening preferably runs relatively steeply to almost perpendicularly with respect to the component upper side.

According to at least one embodiment, there is an acute angle at a lower edge of the removal opening. The lower edge in this case faces toward a base end of the removal tool. The base end is the end of the removal tool that moves ahead in step B1).

According to at least one embodiment, the lower edge is provided with one or more catching structures. The at least one catching structure is adapted to penetrate into the protective film and/or catch on the protective film in step B2). For example, the catching structure is formed by spikes, hooks, barbs and/or teeth.

According to at least one embodiment, the removal tool comprises a shaft. The shaft is preferably the only component part of the removal tool that touches the protective film and therefore comes close to the semiconductor component. The removal opening or the removal openings is or are located in the shaft.

According to at least one embodiment, the shaft of the removal tool is configured in one piece. That is to say, the shaft is then formed by a single component and is preferably inherently immobile.

According to at least one embodiment, the shaft is mechanically rigid. That is to say, during intended use the shaft does not deform or does not deform significantly.

According to at least one embodiment, the shaft of the removal tool comprises a plurality of parts, in particular precisely two parts. The parts may be formed from the same material or from different materials. It is possible that the parts have different thicknesses to one another.

According to at least one embodiment, the parts of the shaft can be displaced relative to one another. It is thereby possible to modify a configuration of the removal opening by a relative movement of the parts with respect to one another and to clamp the removable film in step B2).

According to at least one embodiment, the removal opening at least in step B1) runs in a direction away from the component upper side through the parts of the shaft. That is to say, the removable film may be guided through the entire shaft in step B1). The protective film can therefore be clamped efficiently between the parts only in step B2).

According to at least one embodiment, the removal opening in step B1) is formed by a distance between the parts, in particular by a distance parallel to a movement direction of the removal tool. In particular, one of the parts, or even both parts, is or are free of a through-hole for the removal opening for this reason. In other words, the removal opening runs only partially through the shaft. In step B2), the protective film may then be clamped between the parts, in particular without the protective film penetrating through the shaft.

According to at least one embodiment, the protective film in step A) protrudes beyond the component upper side only at the longitudinal side. It is therefore possible for the protective film to be set back relative to the component upper side or to end flush with the component upper side at one, several or all other sides of the component upper side, as seen in a plan view.

According to at least one embodiment, the protective film consists of one of the following materials or comprises at least one of the following materials: a polyamide, a polyacrylate, a polycarbonate.

According to at least one embodiment, the protective film has an adhesive power with respect to the component upper side of at least 1 N/cm and/or at most 10 N/cm per cm, that is to say an adhesive power of for example 2.5 N per cm of protective film length. A width of an adhesive, for example in the form of a strip, with which this adhesive power is achieved lies for example between at least 0.5 mm and/or at most 5 mm. Preferably, a plurality of, in particular two, such adhesives in the form of a strip are present. For example, a silicone is used as the adhesive. It is possible for the protective film, optionally together with the adhesive, to be thermally stable up to 180° C. and to withstand a temperature of 350° C. briefly, in particular for at most 10 s or 30 s.

According to at least one embodiment, a material of the protective film, and therefore preferably the protective film itself, has a modulus of elasticity of at least 1 GPa or at least 2.5 GPa at 300 K. Alternatively or in addition, this value is at most 8 GPa or at most 4 GPa. It is possible that, at 300 K, a tensile strength of the protective film is at least 0.1 GPa or at least 0.15 GPa and/or at most 0.8 GPa or at most 0.4 GPa.

According to at least one embodiment, a ratio of a height of the removal opening and a thickness of the protective film is at least 1.1 or at least 1.2 or at least 1.5. Alternatively or in addition, this ratio is at most 6 or at most 4 or at most 3. The height of the removal opening is, in particular, determined in a direction perpendicular to the component upper side and along the movement direction of the shaft in step B2).

According to at least one embodiment, a ratio of an overhang of the protective film beyond the longitudinal side to a thickness of the semiconductor component is at least 0.2 or at least 0.5 or at least 0.8. Alternatively or in addition, this ratio is at most 5 or at most 2 or at most 1.2. The overhang is preferably determined when the protective film has not yet been deformed by the tool, i.e. particularly in step A).

According to at least one embodiment, a ratio of the overhang and the thickness of the protective film is at least 5 or at least 10 or at least 20. Alternatively or in addition, this ratio is at most 100 or at most 50 or at most 35.

According to at least one embodiment, the semiconductor component is provided in step A) mounted on a carrier, such as a circuit board. It is possible for there to be only one or a plurality of the semiconductor components on the carrier.

According to at least one embodiment, at least one carrier frame, which forms one or more recesses, is located on the carrier. The semiconductor component is in this case preferably arranged in the recess. In particular, there is a one-to-one correspondence between the at least one recess and the at least one semiconductor component.

According to at least one embodiment, a distance of the semiconductor component from the carrier frame, in particular at the height of the component upper side, at the longitudinal side is at least 0.5 mm or at least 1 mm or at least 2 mm. Alternatively or in addition, this distance is at most 10 mm or at most 5 mm or at most 2.5 mm. It is in this case possible for the distance to be at most 10% or at most 5% and/or at least 1% of a diagonal length of the component upper side. That is to say, the distance may be small in comparison with a diagonal length of the component upper side.

According to at least one embodiment, in step B) the removal tool is guided between the semiconductor component and the carrier frame into the recess. With the removal tool described here, it is therefore possible to separate the protective film in an automated fashion despite the small space laterally next to the semiconductor component.

Furthermore, a removal tool for a method as described in connection with one or more of the embodiments mentioned above is provided. Features of the removal tool are therefore also disclosed for the method, and vice versa.

In at least one embodiment, the removal tool comprises a shaft in which there are one or more removal openings. The removal opening runs as far as a base end of the shaft, for example at an angle of at least 20° and/or at most 70°, in particular from 50° to 60°. A length of the shaft is preferably greater by at least a factor of 10 or 20 or 30 than a distance of the removal opening from the base end. The distance is preferably determined on an outer side of the shaft, as seen from the outside, and then does not refer to a distance of the removal opening from the base end inside the shaft.

Furthermore, a semiconductor component for a method as described in connection with one or more of the embodiments mentioned above is provided. Features of the semiconductor component are therefore also disclosed for the method, and vice versa.

In at least one embodiment, the semiconductor component comprises one or more semiconductor chips, particularly preferably at least one optoelectronic semiconductor chip such as a light-emitting diode chip, a laser diode chip, a CCD chip or a photodiode chip. The semiconductor component furthermore comprises a frame, which circumferentially runs around the at least one semiconductor chip, preferably fully, as seen in a plan view of the component upper side. A protective film, which is fastened at least or only on the frame, is arranged preferably at a distance from the optoelectronic semiconductor chip so that the protective film does not touch the at least one semiconductor chip. The protective film protrudes beyond the component upper side at a longitudinal side of a component upper side, as seen in extension of the component upper side, so that the semiconductor component or the combination of the semiconductor component and the protective film is bounded by the protective film at the longitudinal side as seen in a plan view of the component upper side.

According to at least one embodiment, the at least one optoelectronic semiconductor chip has a multiplicity of pixels. The pixels or groups of pixels are preferably electro-optically drivable independently of one another. For example, there are at least 100 or 10³ or 10⁴ and/or at most 10⁶ or at most 10⁵ of the pixels.

According to at least one embodiment, the at least one optoelectronic semiconductor chip is adapted for the generation of light. For example, the semiconductor chip is intended to emit white or colored light during operation. The light to be emitted may have a fixed spectral composition or may be tunable, for example by the presence of pixels for the emission of white light with different correlated color temperatures or pixels emitting different colors.

A method as described here, a removal tool as described here and a semiconductor component as described here will be explained in more detail below with reference to the drawing with the aid of exemplary embodiments. References that are the same indicate elements that are the same in the individual figures. The relationships represented are not true to scale, however, but instead individual elements may be represented exaggeratedly large for better understanding.

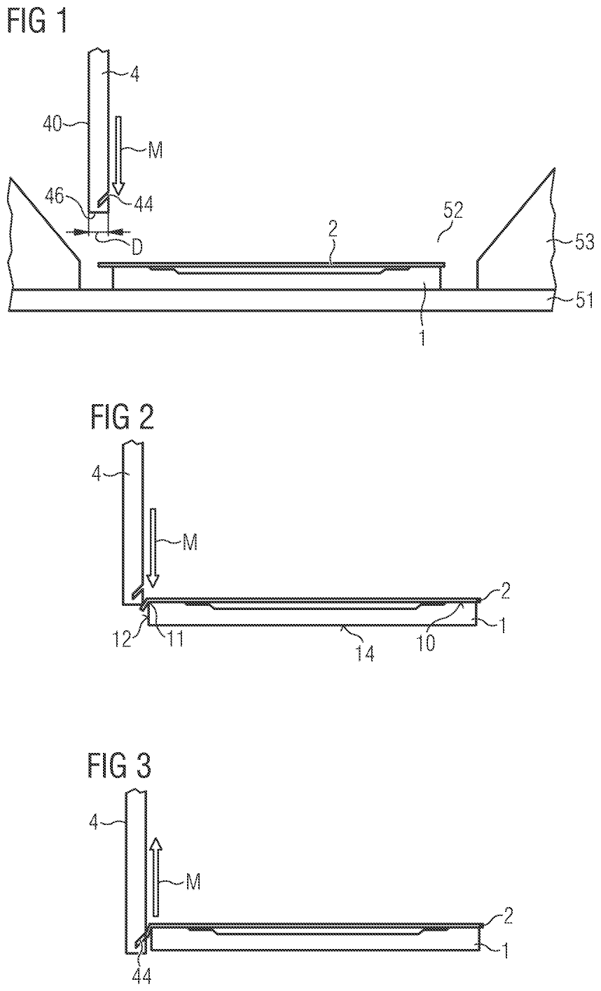

FIGS. 1 to 5 show schematic sectional representations of method steps of an exemplary embodiment of a method for completing semiconductor components as described here,

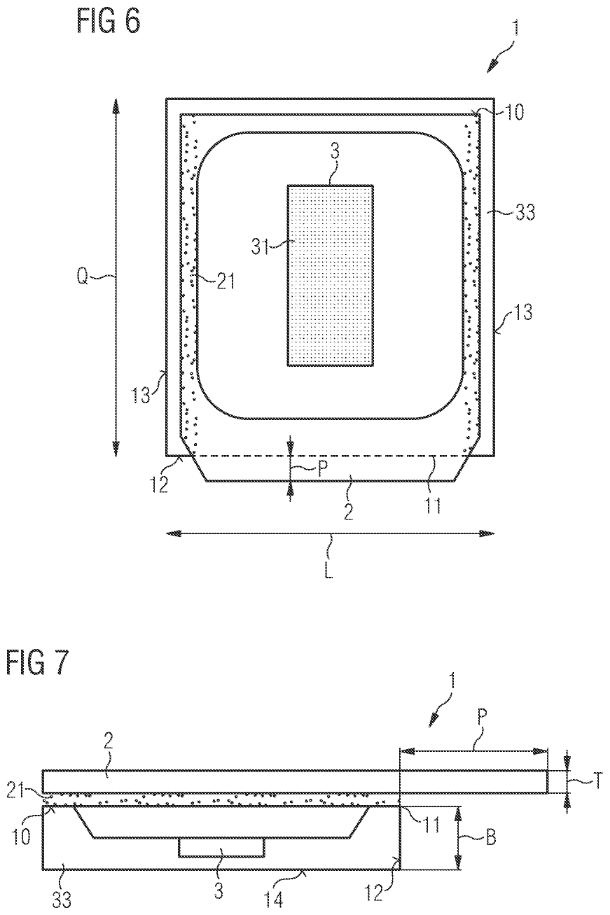

FIG. 6 shows a schematic plan view of an exemplary embodiment of a semiconductor component as described here,

FIG. 7 shows a schematic sectional representation of the semiconductor component of FIG. 6,

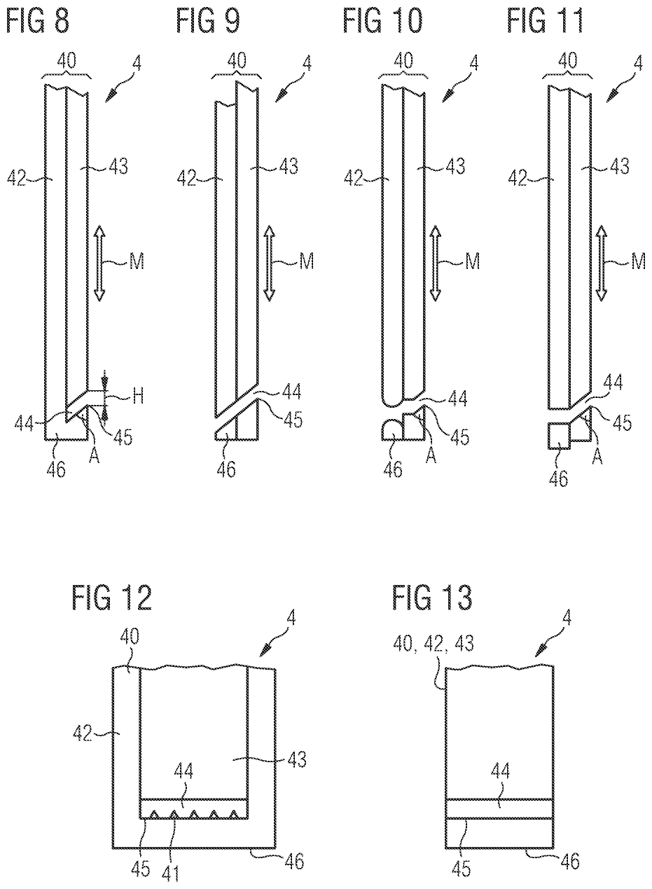

FIGS. 8 to 11 show schematic sectional representations of exemplary embodiments of removal tools for methods as described here, and

FIGS. 12 and 13 show schematic side views of exemplary embodiments of removal tools for methods as described here.

FIGS. 1 to 5 illustrate a method for removing a protective film 2 from a semiconductor component 1. FIG. 1 shows that the semiconductor component 1, which is preferably an optoelectronic semiconductor component for the emission of light, is mounted on a carrier 51, for example by means of soldering.

On the carrier 51, there is a carrier frame 53 which defines a recess 52. The semiconductor component 1 is attached in the recess 52, a distance D between the carrier frame 53 and the semiconductor component 1 being comparatively small, and being for example about 2 mm. For example, the distance D is at least two times and at most six times a mounting tolerance in the placement of the semiconductor component 1 on the carrier 51. The mounting tolerance is for example 0.5 mm. In order to simplify the representation, the carrier 51 and the carrier frame 53 are subsequently no longer shown.

As a variant of the representation of FIG. 1, a multiplicity of the semiconductor components 1 may also be mounted on the carrier 51.

A protective film 2 is fastened on an upper side 10 of the semiconductor component 1. The protective film 2 is preferably adhesively bonded. The protective film 2 may in this case be at a distance from a semiconductor chip of the semiconductor component 1. At a longitudinal side 11, the protective film 2 protrudes beyond the component upper side 10. The protective film 2 is in this case aligned parallel with the component upper side 10 and is flatly shaped.

For example, the protective film 2 is a film of Kapton or polyimide, for example of the type JANUS® K92 KAPTON® from the manufacturer DETAKTA, Norderstedt, Germany, with a thickness of 0.064 mm.

In order to separate the protective film 2, a removal tool 4 is used. The removal tool 2 has a narrow, for example chisel-shaped, shaft 40 so that it fits into a gap between the carrier frame 53 and the semiconductor component 1. At a base end 46, which faces toward the semiconductor component 1 and the carrier 51, the shaft 40 has a removal opening 44. The removal opening 44 is, for example, configured in the form of a slot. A movement direction M of the removal tool 4 is, according to FIG. 1, perpendicular to the component upper side 10 and in a direction toward the carrier 51.

FIG. 2 illustrates that the removal tool 4 is placed on the protective film 2, laterally next to the semiconductor component 1, and presses the protective film 2 downward toward a side face 12 of the semiconductor component 1, which connects the component upper side 10 to an opposite component lower side 14. At a longitudinal side 11 of the component upper side 10, the protective film 2 is thereby creased. Preferably, detachment of the protective film 2 from the component upper side 10 does not yet thereby take place. That is to say, the removal tool 2 at this stage bears down laterally past the protective film 2 toward the carrier 51 and bends the protective film 2.

The method step of FIG. 3 illustrates that the removal tool 4 has moved further past the protective film 2. The removal tool 4 in this case slides along the protective film 2 until a film edge has snapped into the removal opening 44. The removal tool 4 may in this case continue as far as the carrier 51 or be stopped at a distance from the carrier 51.

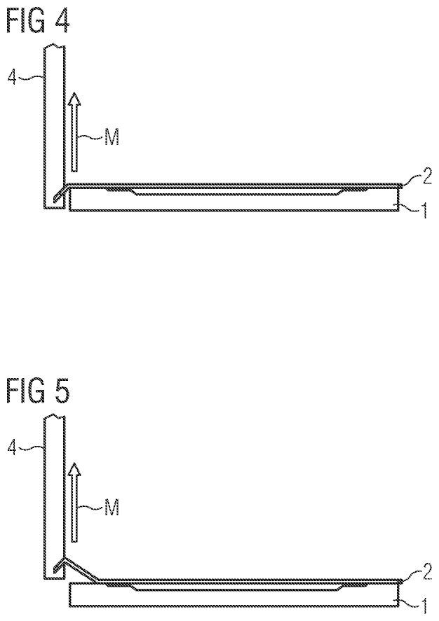

In the method step of FIG. 4, the movement direction M has been reversed so that the removal tool 4 moves away from the carrier 51 again, in a direction perpendicular to the component upper side 10 and back along the same path. The protective film 2 in this case slips further into the removal opening 44 and wedges therein. Because of the shape of the removal opening 44 and the relatively pronounced stiffness of the protective film 2, the protective film 2 is therefore retained in the removal opening 44.

If the removal tool 4 moves further, see FIG. 5, the protective film 2 is drawn continuously upward away from the component upper side 10. The removal tool 4 preferably moves away from the component upper side 10 until the protective film 2 is lifted fully from the component upper side 10. After the protective film 2 has been detached from the component upper side 10, the protective film 2 may continue to be fixed on the removal tool 4 or the protective film 2 is withdrawn in another way, for example by means of an air flow (not shown).

This method allows efficient, secure, reliable and automated detachment and separation of the protective film 2.

FIGS. 6 and 7 represent an exemplary embodiment of a semiconductor component 1 with a protective film 2. The semiconductor component 1 comprises an optoelectronic semiconductor chip 3 having a multiplicity of pixels 33. The at least one semiconductor chip 3 is enclosed circumferentially by a frame 33 as seen in a plan view. The frame 33 is, for example, formed directly on the semiconductor chip 3 and is, for example, produced by casting or injection molding or pressing. The semiconductor chip 3 preferably does not reach as far as the component upper side 10, so that the component upper side 10 may be formed exclusively by the frame 33.

For example, the protective film 2 is fastened on the component upper side 10 only at two transverse sides 13, perpendicularly to the longitudinal side 11, by means of a strip-shaped adhesive 21. A length L of the longitudinal side 11 may be less than a length Q of the transverse side 13. The length L is for example at least 5 mm and/or at most 50 mm. The length Q is for example at least 8 mm and/or at most 80 mm. A thickness B of the semiconductor component 1 between the component upper side 10 and the component lower side 14 is, for example, at least 0.5 and/or at most 5 mm, in particular between 1 mm and 2 mm inclusive.

The protective film 2 protrudes beyond the component upper side 10 only at the longitudinal side 11, and is otherwise set back relative to the component upper side 10, for example by at least 0.1 mm and/or at most 1 mm. At the longitudinal side 11, the protective film 2 may be shaped as a symmetrical or asymmetrical trapezoid.

A thickness T of the protective film 2 is for example at least 20 μm and/or at most 0.2 mm, in particular between 45 μm and 95 μm inclusive. The protective film 2 is for example made of polyamide. An overhang P of the protective film 2 at the longitudinal side 11 beyond the component upper side 10 is for example at least 0.4 mm and/or at most 4 mm. This overhang P is, for example, equal to the thickness B of the semiconductor component with a tolerance of at most a factor of 1.5 or 1.2. Alternatively or in addition, the overhang P is equal to at least 2% or at least 5% and/or at most 25% or at most 15% of the length Q. A thickness of the adhesive 21 is, for example, at least 2 μm and/or at most 0.1 mm.

The values mentioned in the preceding three paragraphs may apply individually, altogether or in any desired combination.

Such a semiconductor component 1 together with the protective film 2, as illustrated in FIGS. 6 and 7, may be used in all other exemplary embodiments, particularly in the method of FIGS. 1 to 5.

Various configuration possibilities of the removal tool 4, which may be used in all exemplary embodiments, are illustrated in FIGS. 8 to 13.

Unlike in the method of FIGS. 1 to 5, the removal tools 4 of FIGS. 8 to 13 are respectively configured in multiple parts, particularly in two parts. That is to say, the shaft 44 is in particular composed of a first part 43 and a second part 42, the parts 43, 42 being mobile relative to one another. The first part 43 is in this case respectively intended to face toward the protective film 2 to be removed.

According to FIG. 8, the parts 43, 42 may be free of holes. The second part 42, as seen in cross section, is configured in the form of a hook and defines an overall thickness of the shaft 40. The second part 42 forms a lower edge 45 of the removal opening 44 and a base end 46 of the shaft 40. At the lower edge 45, the removal opening 44 makes for example an acute angle A of about 45° with a front side, which ends flush or approximately flush with the first part 43, of the second part 42.

The first part 43 is mobile parallel to the second part 42 along an intended movement direction of the shaft 40 during the method. In method steps corresponding to FIGS. 1 to 3, a height H of the removal opening 44 is preferably at least 1.5 times and/or at most three times a thickness T of the protective film 2 for which the removal tool 4 is intended. The same may also apply in all other exemplary embodiments.

In the method steps corresponding to FIGS. 4 and 5, the first part 43 is moved toward the lower edge 45 so that the protective film 2 to be removed is clamped between the parts 43, 42. The lower edge 45 is in this case preferably sharp-edged in order to improve wedging or hooking of the protective film 2 with the shaft 40.

In the exemplary embodiment of FIG. 9, the removal opening 44 extends through both parts 43, 42 so that a continuous channel for the removal opening 44 is formed in the method steps corresponding to FIGS. 1 to 3. In the steps of the method corresponding to FIGS. 4 and 5, the parts 43, 42 are displaced relative to one another so that the protective film 2 can be clamped. An additional holding effect may in this case be achieved by the sharp edge, facing toward the base end 46, on the removal opening 44 of the second part 42, which is located close to the first part 43.

FIG. 10 illustrates that the second part 42 may have round contours in the region of the removal opening 44. A risk of shearing the protective film 2 due to a relative movement of the parts 42, 43 with respect to one another may thereby be reduced.

FIG. 10 furthermore shows that the removal opening 44 may have two regions, particularly in the first part 43: the removal opening 44 runs more steeply on a side facing toward the protective film 2 to be removed, and becomes shallower toward the second part 42. What this renders achievable is that a distance between the base end 46 and the removal opening 44 may be less on the side of the first part 43 facing toward the protective film 2 to be removed than with a removal opening 44 having a constant slope. The same applies for all other exemplary embodiments.

FIG. 11 illustrates that the removal opening 44 may be formed in the shape of a wedge so that the removal opening 44 tapers in the direction toward the second part 42. There may also be such a configuration in all other exemplary embodiments.

FIG. 11 furthermore represents that the parts 42, 43 need not end flush with the base end 46 in the opened state of the removal tool 4, i.e. in the method steps corresponding to FIGS. 1 to 3. For example, the second part 42 protrudes beyond the first part 43 toward the base end 46, or vice versa. When the shaft 40 is placed on the carrier 51 (not shown), this offset of the parts 42, 43 with respect to one another may lead to automatic retention of the protective film 2 in the removal opening 44. There may also be such a configuration in all other exemplary embodiments.

According to FIG. 12, the second part 42 has a larger width than the first part 43 as seen in a plan view along the longitudinal side 11. This applies in particular for configurations of the removal tool 4 according to FIGS. 9 to 11. Conversely, the parts 42, 43 are equally wide according to FIG. 13. This may, for example, apply for removal tools according to FIG. 8. The removal opening 44 may therefore extend predominantly or entirely transversely across the parts 42, 43.

FIG. 12 furthermore illustrates that there may be one or more catching structures 41, in particular on the lower edge 46 of the removal opening 44. The at least one catching structure 41 is, for example, formed by a spike or a barb. There may also be such a configuration in all other exemplary embodiments.

The component parts shown in the figures preferably follow one another in the order indicated, in particular directly after one another, unless otherwise described. Component parts that do not touch in the figures preferably have a distance from one another. When lines are shown parallel to one another, the associated faces are preferably likewise aligned parallel to one another. Furthermore, the relative positions of the shown component parts with respect to one another are reproduced correctly in the figures unless otherwise indicated.

The invention described here is not restricted by the description with the aid of the exemplary embodiments. Rather, the invention comprises any new feature and any combination of features, which in particular includes any combination of features in the patent claims, even if this feature or this combination is not itself explicitly specified in the patent claims or the exemplary embodiments.

This patent application claims the priority of German Patent Application 10 2020 129 064.0, the disclosure of which is incorporated here by reference.

### LIST OF REFERENCES

1 semiconductor component
10 component upper side
11 longitudinal side of the component upper side
12 side face of the semiconductor component
13 transverse side of the component upper side
14 component lower side
2 protective film
21 adhesive
3 optoelectronic semiconductor chip
31 pixel
33 frame
4 removal tool
40 shaft
41 catching structure
42 second part of the shaft
43 first part of the shaft
44 removal opening
45 lower edge
46 base end of the shaft
51 carrier
52 recess
53 carrier frame
A angle of the removal opening with respect to the semiconductor component
B thickness of the semiconductor component without protective film
D semiconductor component—carrier frame distance
H height of the removal opening
L length of the semiconductor component on the longitudinal side
M movement direction of the removal tool
P overhang of the protective film
Q length of the semiconductor component on the transverse side
T thickness of the protective film

1. A method for removing a protective film from a semiconductor component, having the steps:
A) providing the semiconductor component having the protective film on a component upper side,
B) separating the protective film from the component upper side with a removal tool, which has a removal opening,
wherein the protective film in step A) protrudes beyond the component upper side at a longitudinal side, as seen in extension of the component upper side, and
wherein step B) comprises the following substeps:
B1) guiding the removal tool next to the semiconductor component along the longitudinal side in a direction transverse to the component upper side while it bears on the protective film, so that the protective film is bent by the removal tool in a direction toward a side face of the semiconductor component, and
B2) retracting the removal tool so that the protective film catches in the removal opening and the protective film is detached from the component upper side.

2. The method as claimed in claim 1,
wherein the protective film in step A) is fastened on the semiconductor component by means of an adhesive, and
wherein the adhesive is applied only along two mutually opposite transverse sides of the component upper side.

3. The method as claimed in claim 1,
wherein the removal opening is formed by a slot which extends along the longitudinal side, and
wherein the slot extends at an angle of at least 30° and at most 60° away from the component upper side and toward a component lower side.

4. The method as claimed in claim 1, wherein a lower edge of the removal opening, at which there is an acute angle, is provided with at least one catching structure, which is adapted to penetrate into the protective film in step B2).

5. The method as claimed in claim 1, wherein a shaft of the removal tool, in which the removal opening is located, is configured in one piece and mechanically rigidly.

6. The method as claimed in claim 1, wherein a shaft of the removal tool comprises two parts that can be displaced relative to one another,
wherein the removal opening in step B1) runs in a direction away from the component upper side through both parts, so that in step B2) the protective film is clamped between the parts.

7. The method as claimed in claim 1,
wherein a shaft of the removal tool comprises two parts that can be displaced relative to one another,
wherein the removal opening in step B1) is formed by a distance between the parts parallel to a movement direction of the removal tool in step B) and the removal opening runs only partially through the shaft, so that in step B2) the protective film is clamped between the two parts.

8. The method as claimed in claim 1, wherein the protective film in step A) protrudes beyond the component upper side only at the longitudinal side and at all other sides of the component upper side is set back relative to the component upper side as seen in a plan view.

9. The method as claimed in claim 1, wherein the protective film consists of one of the following materials or comprises at least one of the following materials: a polyamide, a polyacrylate, a polycarbonate.

10. The method as claimed in claim 1, wherein a ratio of a height of the removal opening and a thickness of the protective film lies between 1.2 and 4 inclusive.

11. The method as claimed in claim 1, wherein a ratio of an overhang of the protective film beyond the longitudinal side to a thickness of the semiconductor component lies between 0.5 and 2 inclusive and/or a ratio of the overhang and a thickness of the protective film lies between 10 and 50 inclusive.

12. The method as claimed in claim 1, wherein
in step A) the semiconductor component is provided mounted on a carrier and a carrier frame, which forms a recess, is located on the carrier,
the semiconductor component is arranged in the recess and a distance of the semiconductor component from the carrier frame at the height of the component upper side at the longitudinal side is between 0.5 mm and 5 mm inclusive, and
in step B) the removal tool is guided between the semiconductor component and the carrier frame into the recess.

13. A removal tool for a method as claimed in claim 1, having a shaft in which the removal opening is located, wherein
the removal opening runs as far as a base end of the shaft, and
a length of the shaft is greater by at least a factor of 20 than a distance of the removal opening from the base end.

14. A semiconductor component for a method as claimed in claim 1, having
an optoelectronic semiconductor chip,
a frame, which circumferentially runs fully around the optoelectronic semiconductor chip as seen in a plan view of the component upper side, and
the protective film which is fastened on the frame and is separated from the optoelectronic semiconductor chip,
wherein the protective film protrudes beyond the component upper side at a longitudinal side, as seen in extension of the component upper side, so that the semiconductor component is bounded by the protective film at the longitudinal side as seen in a plan view of the component upper side.

15. The semiconductor component as claimed in claim 1,
wherein the optoelectronic semiconductor chip has a multiplicity of pixels and is adapted for the generation of light.
